(19) United States
(12) Patent Application Publication
(10) Pub. No.: US 2009/0052127 A1
(43) Pub. Date: Feb. 26, 2009

(54) Electrical appliance housing having an indirect magnetic controlling kit

(76) Inventor: CHI-WEN KUO, Taipei (TW)

Correspondence Address: Eric Chan, 42 Pin Oaks Drive, Phoenixville, PA, 19460, US

(21) Appl. No.: 11/845,038

(22) Filed: Aug. 25, 2007

(51) Int. Cl. H05K 5/03; H05K 5/00

(52) U.S. Cl. 361/680; 361/679

(57) ABSTRACT

This invention provides an electrical appliance housing comprising a main body and a lid. At least one magnetic controlling assembly is provided on the housing, comprising a sliding key that shifts in a sliding groove. The sliding key further includes a pair of controlling magnets with opposing magnetic polarity. An actuating magnet is installed inside of the housing and corresponds to a specific controlling key of the electrical appliance. Shifting the sliding key will produce a magnetic force relative to the actuating magnet, and this force in turn activates the controlling key of the electrical appliance. In addition, at least one functional device is installed on the lid that corresponds to the specific functional key of the electrical appliance, comprising a pair of blind holes situated so to correspond with one another. An actuating magnet is installed in the inner hole and a controlling magnet is fixed on the bottom of the sliding key which has the same magnetic polarity with said actuating magnet. Placing the controlling magnet opposite the actuating magnet can control the functional key. Because the housing of the present invention has not penetrated by any holes, the electrical appliance is indirectly controlled by the magnetic operating kits.

### BACKGROUND OF THE INVENTION

The present invention relates to housing for an electrical appliance. More particularly, the present invention relates to a housing with indirect magnetic operating kits that are used for controlling an electrical appliance underwater or outdoors.

When operating electrical equipment, such as a mobile phone, personal digital assistant (PDA), global positioning system (GPS), camera or the like, in an outdoor or underwater environment, the primary purpose of the housing in which the equipment is stored is to provide an effective means of waterproofing to prevent leakage into the housing that may cause damage to the electrical components of the equipment. Presently there is no device that can ensure both proper operation and total waterproofing of an electrical appliance when used in an outdoor or underwater environment.

One conventional waterproofed housing for a camera is shown in FIG. 9, which is a perspective view schematically showing such conventional housing. Housing 1a comprises a main body 2a and a lid 3a, where the lid 3a is sealed and connected with the main body 2a pivotally and has a viewing window 31a on the lid 3a. The lid 3a also forms a controlling panel for the housing 1a and has several controlling keys 32a which correspond to the functional keys (not shown) of the camera. The controlling keys 32a of the lid 3a are made of stainless steel and pass through the lid 3a in order to make direct contact with the function keys of the camera. The lid 3a includes multiple through holes 33a through which the said controlling keys 32a pass, and each controlling key 32a comprises a cylindrical button 321a, a spring 322a, an O-ring 323a, a C-type clamp 324a and a rubber cap 325a. In light of the structure given above, the user can operate the camera underwater by pushing the cylindrical button 321a from the outside of the lid 3a and this force will be directly transmitted to the camera's functional keys via the rubber cap 325a.

The aforesaid conventional method for storing and operating the camera underwater is achieved by using a controlling key 32a installed on the lid 3a of the housing 1a. However, the aforesaid method contains some improvable defects, such as:

1. Ageing of parts: due to the fact that the O-ring 323a is made of rubber, it ages and becomes less effective when used for a period of time, and this could result in leakage.

2. Failure at increased water depth: as depth underwater is increased, water pressure increases as well. Under high pressure, the O-ring 323a will deform, resulting in leakage at the contact surface of the cylindrical button 321a and the O-ring 323a.

The present invention is intended to improve upon the above mentioned drawbacks.

### BRIEF SUMMARY OF THE INVENTION

The primary object of the present invention is to provide an electrical appliance housing that prevents leakage by using a magnetic operating kit to indirectly control the electrical appliance stored in said housing. This method can ensure the waterproofing and gas-proofing abilities of the housing when the appliance is used in an underwater or outdoor environment. To achieve the aforesaid result, the present invention provides an electrical appliance housing which comprises a main body and a lid. At least one magnetic controlling assembly is provided on the housing which corresponds to at least one controlling key of the electrical appliance. The magnetic controlling assembly further comprises sliding groove cuts on the surface of the housing containing an assembling structure, such as dovetailed trough, and a sliding key which has a similar structure to the sliding groove, such as dovetailed tenon, such that it is able to assemble with the sliding groove and shift in the groove. The sliding groove is only etched on the surface of the housing, and therefore the housing has not been penetrated. In addition, a blind hole is defined on the inner side of the housing, situated at a location corresponding to the sliding groove, and an actuating magnet is installed inside of the blind hole, enabling control of the specific controlling key of the electrical appliance. A pair of controlling magnets are installed on the sliding key where the two controlling magnets are adjacent and have opposing magnetic polarity in order to produce a repelling magnetic force with said actuating magnet. When the sliding key is shifted in the sliding groove, the controlling key of the electrical appliance can be controlled by the magnetic interaction of two controlling magnets and the actuating magnet situated inside of the housing, which in turn control a specific controlling key of the electrical appliance.

The other object of the present invention is to provide an optional device which can control a specific functional key of the electrical appliance. The device comprises at least one actuating magnet situated inside of the housing and which corresponds to said specific functional key. Additionally, a controlling magnet is fixed on the bottom end of the sliding key and has the same magnetic polarity as said actuating magnet. When the sliding key has been drawn out from the sliding groove and its bottom controlling magnet has been placed upon the housing that corresponds to said actuating magnet, the actuating magnet will be repelled by the magnetic force and will in turn press the specific functional key.

In light of the above, the advantages of the present invention are detailed below:

1. The present invention uses magnetic actuating magnets and controlling magnets which are installed in both sides of the housing such that the electrical appliance can be controlled by shifting the sliding key to create a repulsive magnetic force between the magnets. Therefore, it is not necessary to provide a through hole or use waterproof components, e.g., an O-ring, on such housing. The problems of incomplete waterproofing and component ageing can be avoided.

2. Operation of the electrical appliance housed in the present invention is achieved via an indirect method, and as such there are no holes on the housing. Therefore, there is no possibility of leakage when the housed electrical appliance is submerged in deep water or a high vacuum environment, and operation of the equipment can be carried out normally.

Another object of the present invention is to provide a sliding key with an auto-return mechanism. When the sliding key has been shifted upward along the sliding groove, the controlling magnet of the sliding key, which has the same magnetic polarity as the actuating magnet, approaches the actuating magnet and forces the actuating magnet to press the controlling key of the electrical appliance. When the sliding key is released, because the controlling magnet and the actuating magnet are not positioned along the same axis, resulting in a different level of magnetic potential energy, which further causes the sliding key to pull back because of the magnetism. Meanwhile, the other adjacent controlling magnets bearing opposing magnetic polarity also attract the actuating magnet once the sliding key is drawn backward. This results in the sliding key being automatically returned to the original position and the actuating magnet being withdrawn from pressing on the controlling key as well.

In light of the above, the present invention provides an electrical appliance housing having a magnetic controlling kit which is convenient for operating an electrical appliance underwater or outdoors. The present invention also provides a magnetic controlling kit which is applicable to the controlling or functional keys of the electrical appliance. Additionally, the housing has not been penetrated. The electrical appliance is indirectly operated using the magnetic operating kit, securely waterproofing and gas proofing the appliance.

Other objects, advantages and novel features of the invention will become more apparent in the following detailed description taken in conjunction with the accompanying diagrams.

### BRIEF DESCRIPTION OF THE DRAWINGS

FIG. 1 is a perspective view schematically showing the electrical appliance housing of the present invention;

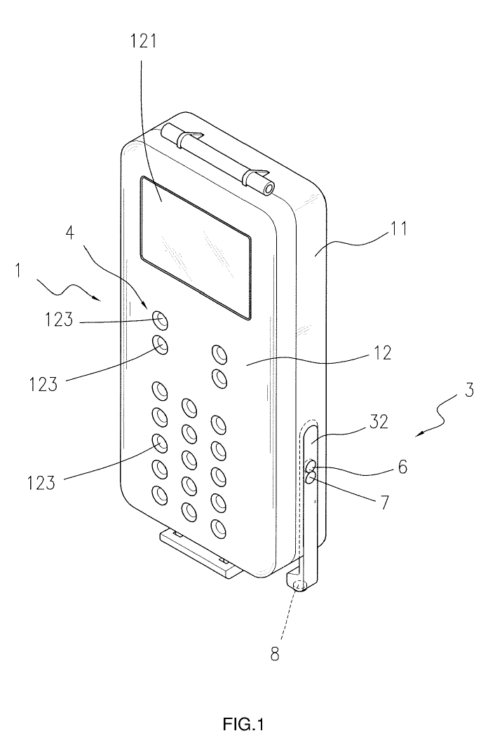

FIG. 2 is a segmented view schematically showing the electrical appliance housing of the present invention;

FIG. 3 is a cross-sectional view schematically showing the combination of the housing of the present invention and a mobile phone;

FIG. 4 is another cross-sectional view schematically showing the combination of the housing of the present invention and a mobile phone;

FIG. 5 is a cross-sectional view schematically showing the assembly of the sliding key and sliding groove of the present invention;

FIG. 6 is a front elevational view schematically showing the electrical appliance housing of the present invention;

FIG. 7 is a partial cross-sectional view schematically showing the operation of the functional key of the present invention;

FIG. 8 is another partial cross-sectional view schematically showing the operation of the functional key of the present invention; and

FIG. 9 is a segmented view schematically showing the conventional electrical appliance housing.

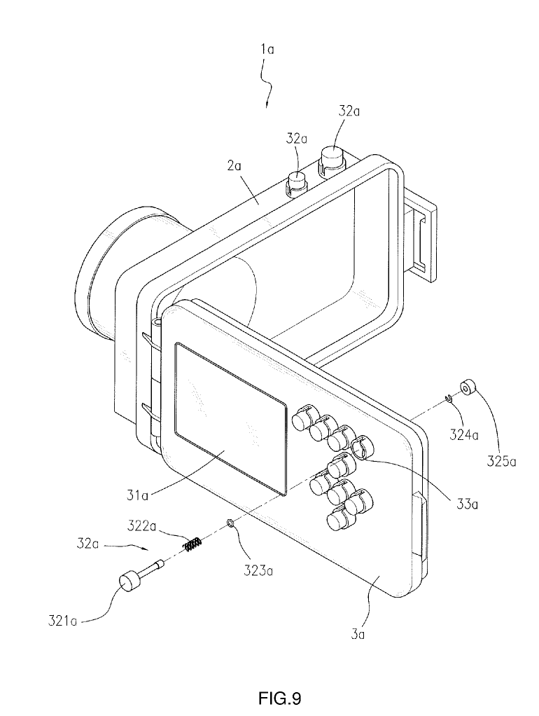

### DETAILED DESCRIPTION OF THE INVENTION

While this invention is capable of embodiment in many different forms, shown in the drawings and herein described in detail is the preferred embodiment of the invention. The preferred embodiment is disclosed with the understanding that the present description is but one example of the principles of the invention and is not intended to limit the broad aspects of the invention to the single embodiment illustrated.

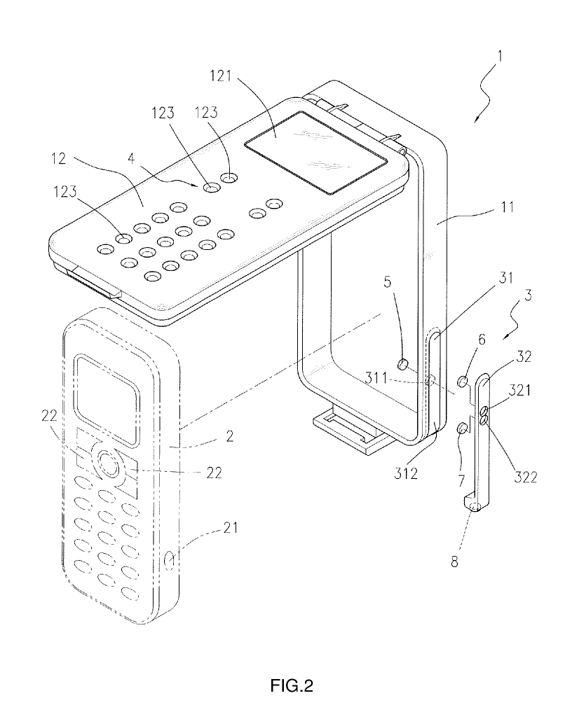

FIG. 2 is a segmented view schematically illustrating the electrical appliance housing of the present invention. For the purpose of description and clarification of the present invention, a mobile phone housing 1 is given as an example of the present invention. However, the given example is merely one possible embodiment and is not intended to limit the scope of the present invention.

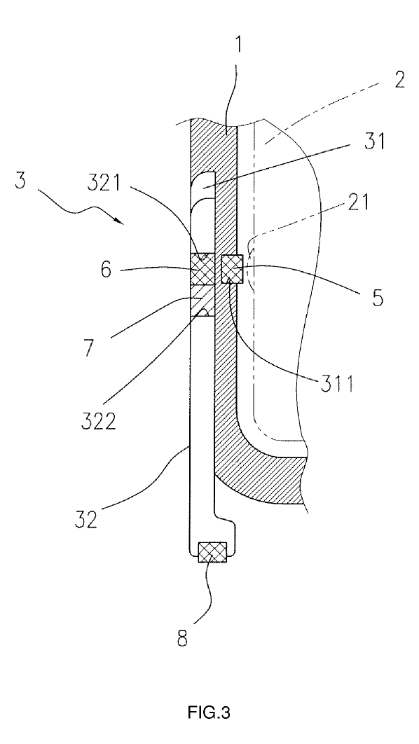

FIGS. 2 and 3 are a segmented view and a cross-sectional view schematically illustrating the electrical appliance housing.

The housing 1 comprises a main body 11 and a lid 12, which is sealed and connected with said main body 11 pivotally. The housing 1 provides an inner space which allows for storing the mobile phone 2, which can be operated from the housing 1. The panel is located on the lid 12 of the housing 1 and has a viewing window 121 to review the status of the operation of the mobile phone 2. At least one magnetic controlling assembly 3 is installed on the housing 1 so that it corresponds to the specific controlling key 21 of the mobile phone 2 (such as the shutter button of the camera). In addition, at least one functional device 4 is installed on the lid 12 such that it corresponds to the specific functional key 22 of the mobile phone 2 (such as the call button, end button or number button).

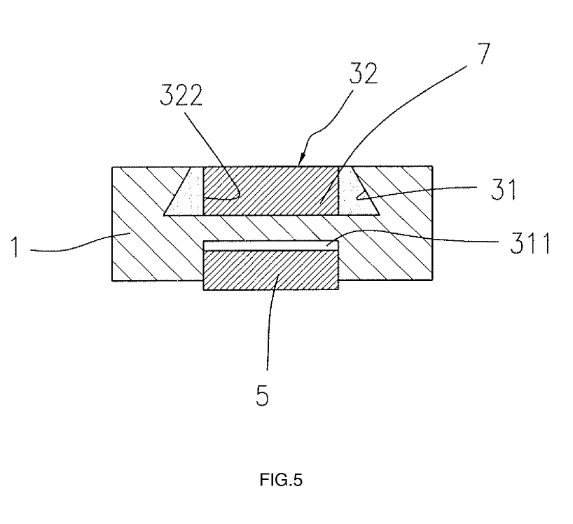

FIGS. 2 to 5 are segmented and cross-sectional views schematically illustrating the electrical appliance housing of the present invention. The controlling assembly 3 comprises a sliding groove 31 cut on the surface of the housing 1 and extends down to the bottom of the housing 1. The bottom end of the sliding groove 31 is an opening end. The structure of the sliding groove 31 is a dovetailed trough, and a sliding key 32 which has a dovetailed tenon corresponding to the sliding groove 31, and is able to assemble with the sliding groove 31. In addition, the bottom end of the sliding key 32 is an inner-bending design which extends downwardly from the housing 1 in order to provide for handheld operation. It is also convenient for withdrawing and assembling the sliding key 32 from the sliding groove 31. Moreover, a controlling magnet 8 is fixed on the bottom end of the sliding key 32 which corresponds to the functional device 4 installed on the lid 12.

In addition, a blind hole 311 is defined on the inner side of the housing 1 and is situated such that it corresponds to the sliding groove 31, and an actuating magnet 5 is installed inside of the blind hole 311, which corresponds to a specific controlling key 21 of the mobile phone 2 (such as shutter button of a camera). Moreover, a pair of assembling holes 321,322 are defined on the sliding key 32 which affix the respective controlling magnets 6, 7 to the corresponding assembling holes 321,322. The two controlling magnets 6, 7 have opposing magnetic polarity and are adjacent to one another, causing them to produce a magnetic force with the actuating magnet 5. The controlling magnet 6 has a magnetic polarity opposite that of the actuating magnet 5, so the magnets attract. Inversely, the controlling magnet 7 has the same magnetic polarity as the actuating magnet 5, so the resultant force is repulsive.

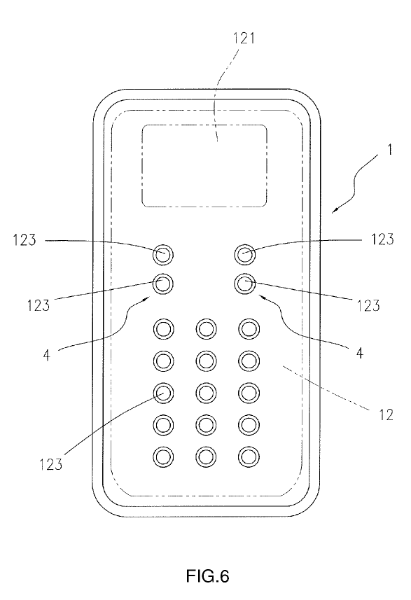

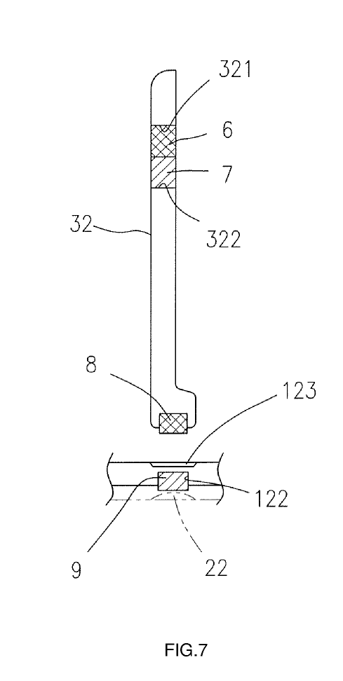

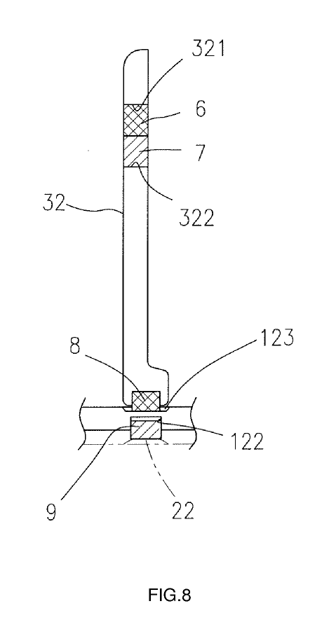

FIGS. 6 to 8 are front elevational and cross-sectional views, respectively, schematically illustrating the electrical appliance housing of the present invention. The functional device 4 comprises a pair of blind holes 122, 123 which are defined on the inner side and outer side of the lid 12, and neither pair of holes penetrates completely through the lid 12. The inner blind hole 122 is used for installing an actuating magnet 9 which corresponds to a functional key 22 of the mobile phone 2 (such as the call button, end button or number button). The outer blind hole 123 is a recessing hole and is used for positioning the controlling magnet 8 of the sliding key 32. The magnetic polarity of the controlling magnet 8 and actuating magnet 9 is the same. When the controlling magnet 8 of the sliding key 32 is placed on the blind hole 123 opposite the actuating magnet 9, the actuating magnet 9 will be repelled and forced into the functional key 22 of the mobile phone 2 (as shown in FIG. 8), initiating the function of the key 22 that is pressed. To reverse this action, the sliding key 32 is removed from the outer blind hole 123 (as shown in FIG. 7), and the functional key 22 will then be returned to the original position due to the elasticity of the button itself, which further pushes the actuating magnet 9 back into the inner blind hole 122.

In light of the above, the present invention provides an optional device for indirectly operating the mobile phone 2 stored in the housing 1 via a magnetic operating method.

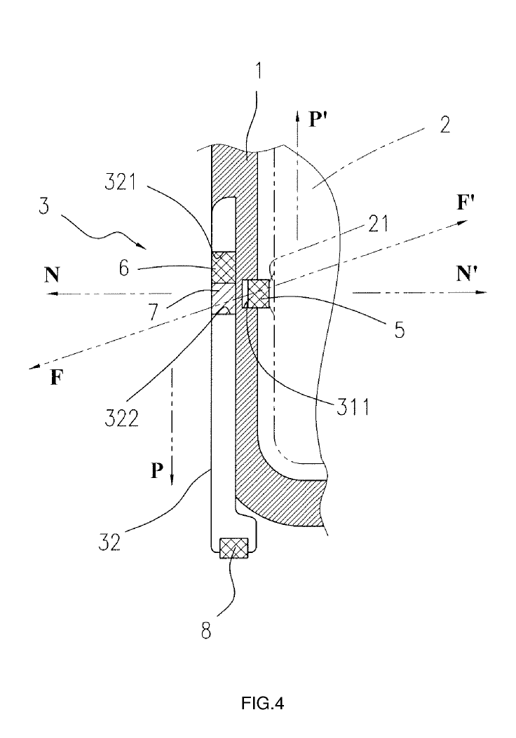

FIGS. 3 and 4 are cross-sectional views schematically showing the combination of the housing of the present invention and a mobile phone. When the sliding key 32 has been shifted along the sliding groove 31, the controlling magnets 6, 7 of the sliding key 32 will produce the actions of attraction and distraction with the actuating magnet 5, which is installed inside of the housing 1. This results in the operation of the controlling key 21. When the controlling magnet 6 of the sliding key 32, which has a magnetic polarity different from the actuating magnet 5, stays at the position corresponding to the actuating magnet 5 (as shown in FIG. 3), the controlling magnet 6 and actuating magnet 5 will be attracted to one another. The actuating magnet 5 will disengage the controlling key 21 of the mobile phone 2, toggling the controlling key 21 to “OFF”. Similarly, when the controlling magnet 7 of the sliding key 32, which has the same magnetic polarity as the actuating magnet 5, approaches the actuating magnet 5 (as shown in FIG. 4), it forces the actuating magnet 5 to press the controlling key 21 of the mobile phone 2. Furthermore, in order to make sure the sliding key 32 will be returned to the original position in the sliding groove 31 automatically, the route of the sliding key 32 in the sliding groove 31 is limited. More specifically, an upper dead point and a lower dead point are defined in the sliding groove 31. When the controlling magnet 6, which has magnetic polarity different from the actuating magnet 5, shifts to a position corresponding to the actuating magnet 5, it is the lower dead point of the sliding key 32. However, as the controlling magnet 7, which has the same magnetic polarity as the actuating magnet 5, slides in parallel direction toward the position corresponding to the actuating magnet 5, the position of the projection of the controlling magnet 7 is covered by the actuating magnet 5 at most 95%, it is the upper dead point of the sliding key 32. When the sliding key 32 is released, because the controlling magnet 7 and the actuating magnet 5 do not remain at the same axis resulting in the magnetic line of force (F-F′) creating a horizontal component of force (N-N′) and a vertical component of force (P-P′) (as shown in FIG. 4. This will cause a different level of magnetic potential energy; wherein the vertical component of force (P-P′) will push the controlling magnet 7 along in the opposite direction once the sliding key 32 has been released. Additionally, the adjacent controlling magnet 6, which has a magnetic polarity different from the actuating magnet 5, also attracts the actuating magnet 5 when the sliding key 32 is pulled backward. The result is the sliding key 32 has returned to the original position automatically and the actuating magnet 5 is withdrawn and no longer presses the controlling key 21 of the mobile phone 2 (as shown in FIG. 3). In light of the above, the present invention provides an auto-return mechanism which can enhance the convenience of the operation of the controlling assembly 3. Additionally, the effective dimension of the magnetic force will be increased which makes the operation of the controlling assembly 3 more precise.

Although numerous characteristics and advantages of the present invention have been set forth in the foregoing description, together with details of the structure and function of the invention, this disclosure illustrates a few examples only, and changes may be made with regard to specific details, particularly in matters of shape, size, and arrangement of parts within the invention to the full extent indicated by the general meaning of the terms in which the appended claims are expressed.

What is claimed is:

1. An electrical appliance housing, comprising:
a main body;
a lid sealed and connected with the main body pivotally; and
at least one magnetic controlling assembly on the housing,
wherein the electrical appliance is operated by shifting the magnetic controlling assembly which utilizes a magnetic force to indirectly control the electrical appliance; the housing is sealed and contains no holes, so the housing is completely waterproof and gas proof.

2. The housing of claim 1, wherein the controlling assembly comprises:
at least one sliding groove cut into the surface of the housing and extending downward to the bottom of the housing; the bottom end of the sliding groove is an open end;
at least one sliding key is assembled with the sliding groove; the bottom end of the sliding key extends from the housing, and a controlling magnet is fixed on the bottom end of the sliding key;
at least one actuating magnet is installed inside of the housing and is situated such that it corresponds to the sliding groove; the actuating magnet is also corresponded to the specific controlling key of the electrical appliance;
two adjacent controlling magnets are installed on the sliding key and have opposing magnetic polarity; the controlling magnets are corresponded to the actuating magnets installed inside of the housing; one of the controlling magnets has the same magnetic polarity as the actuating magnet, and the other has a magnetic polarity different from the actuating magnet;
When the sliding key has been shifted along the sliding groove, the controlling magnets of the sliding key attract and distract the actuating magnet, which is installed inside of the housing, such that the controlling key of the electrical appliance is controlled by the sliding key on the housing without actually penetrating the housing.

3. The housing of claim 2, wherein a blind hole is defined on the inner side of the housing and situated at a location corresponding to the sliding groove, and the actuating magnet is installed inside of the blind hole; in addition, a pair of assembling holes are defined on the sliding key which are used for affixing the adjacent controlling magnets with the opposing magnetic polarity to the assembling holes.

4. The housing of claim 2, wherein the sliding groove of the housing further comprises a dovetailed trough, and the sliding key which has a dovetailed tenon corresponding to the sliding groove; this provides for the assembly of the sliding key and sliding groove, and allows the sliding key to shift in the sliding groove.

5. The housing of claim 2, wherein the controlling magnet and actuating magnet attract one another when the controlling magnet of the sliding key, which has a magnetic polarity different from the actuating magnet, is positioned to correspond with the actuating magnet; this causes the actuating magnet to be removed from the controlling key of the electrical appliance, thereby disengaging the function of the controlling key; inversely, when the controlling magnet of the sliding key having the same magnetic polarity as the actuating magnet approaches the actuating magnet, it forces the actuating magnet to press the controlling key of the electrical appliance, therefore the function of the controlling key is “ON”.

6. The housing of claim 5, wherein the controlling magnet, which has a magnetic polarity different from the actuating magnet, is the one dead point of the sliding key once the controlling magnet is shifted into a position corresponding to the actuating magnet.

7. The housing of claim 5, wherein the controlling magnet, which has the same magnetic polarity as the actuating magnet, is the other dead point of the sliding key when the controlling magnet slides in parallel direction toward the position corresponding to the actuating magnet, at the position of the projection of the controlling magnet is covered by the actuating magnet at most 95%.

8. The housing of claim 1, wherein the bottom end of the sliding key is an inner bending design which extends downward from the housing, providing for handheld operation, and the controlling magnet is fixed on the bottom end of the bending.

9. The housing of claim 1 further comprising at least one functional device installed on the appropriate place of the lid such that it corresponds to the specific functional key of the electrical appliance, comprising:
a pair of blind holes defined on the inner side and outer side of the lid, correspondingly, and neither of them penetrate the lid;
at least one actuating magnet installed in the inner blind hole and corresponded to the functional key of the electrical appliance; the magnetic polarity of the actuating magnet and the controlling magnet situated at the bottom of the sliding key is the same, and thus when the controlling magnet is placed on outer side blind hole and corresponded to the actuating magnet, the actuating magnet is repelled;
when the controlling magnet of the sliding key is placed on the outer blind hole, the actuating magnet situated in the inner hole is repelled due to the identical magnetic polarity; this repulsion in turn presses the functional key of the electrical appliance, turning “ON” the function of that key; on the contrary, when the sliding key is removed from the outer blind hole, the functional key is returned to the original position because of the elasticity of the appliance button itself; this further pushes the actuating magnet back into the inner blind hole, turning “OFF” the function of that key.

10. The housing of claim 9, wherein the outer blind hole is a recessed hole.
